(19) United States
(12) Patent Application Publication
(10) Pub. No.: US 2025/0081789 A1
(43) Pub. Date: Mar. 6, 2025

(54) DISPLAY APPARATUS

(71) Applicant: Samsung Display Co., Ltd., Yongin-si (KR)

(72) Inventors: Daeho Lee, Yongin-si (KR); Hyunwoo Noh, Yongin-si (KR)

(73) Assignee: Samsung Display Co., Ltd., Yongin-si (KR)

(21) Appl. No.: 18/744,182

(22) Filed: Jun. 14, 2024

(30) Foreign Application Priority Data
Sep. 4, 2023 (KR) 10-2023-0117222

(51) Int. Cl. H10K 59/38; H10K 59/122; H10K 59/80; H10K 102/00

(52) U.S. Cl. CPC H10K 59/38; H10K 59/122; H10K 59/8731; H10K 2102/331; H10K 2102/351

(57) ABSTRACT

A display apparatus includes a substrate including a non-display area surrounding a display area, a display element layer disposed on the substrate in the display area and including at least one display element, an encapsulation layer disposed on the display element layer and including at least one inorganic encapsulation layer and at least one organic encapsulation layer, a color conversion-transmissive layer disposed on the encapsulation layer and configured to convert light emitted from the at least one display element into another color, a color filter layer disposed on the color conversion-transmissive layer, and an overcoat layer disposed on the color filter layer and extending from the display area to the non-display area, wherein the overcoat layer comprises a plurality of grooves in the non-display area.

### CROSS-REFERENCE TO RELATED APPLICATIONS

This application claims priority under 35 U.S.C. § 119 from Korean Patent Application No. 10-2023-0117222 filed on Sep. 4, 2023 in the Korean Intellectual Property Office, the entire contents of which are incorporated herein by reference.

### BACKGROUND

### 1. Technical Field

One or more embodiments relate to a display apparatus.

### 2. Description of the Related Art

Due to rapid development in the field of display technology to visually express various types of electrical signal information, various display apparatuses having excellent characteristics such as reduced thickness, lower weight, and lower power consumption have been introduced.

Display apparatuses may include liquid crystal display devices using light from a backlight, instead of autonomously emitting light, or light-emitting display apparatuses including display elements configured to emit light. Light-emitting display apparatuses may include display elements including emission layers.

### SUMMARY

One or more embodiments provide a robust display apparatus. However, the aforementioned technical goal is only an example, and the scope of the disclosure is not limited thereto.

Additional aspects will be set forth in part in the description which follows and, in part, will be apparent from the description, or may be learned by practice of the presented embodiments of the disclosure.

According to one or more embodiments, a display apparatus may a substrate including a display area and a non-display area surrounding the display area, a display element layer disposed on the substrate and including at least one display element, an encapsulation layer disposed on the display element layer and including at least one inorganic encapsulation layer and at least one organic encapsulation layer, a color conversion-transmissive layer disposed on the encapsulation layer and configured to convert light emitted from the at least one display element into another color, a color filter layer disposed on the color conversion-transmissive layer, and an overcoat layer disposed on the color filter layer and extending from the display area to the non-display area, wherein the overcoat layer may include a plurality of first grooves in the non-display area.

A bottom surface of the overcoat layer may include a concave surface corresponding to a convex surface included in a top surface of the color filter layer.

The overcoat layer may be in direct contact with the color filter layer and cover an edge of the color filter layer.

The plurality of first grooves may expose at least a portion of the top surface of the color filter layer.

A center width of each of the plurality of first grooves may be in a range of about 1 μm to about 100 μm.

The overcoat layer may include an organic layer.

A thickness of the overcoat layer may be greater than a thickness of the color filter layer.

A thickness of the overcoat layer may be in a range of about 3 μm to about 8 μm.

The display apparatus may further include a sub capping layer directly contacting the overcoat layer and overlapping the plurality of first grooves.

The display apparatus may further include a first bank layer disposed on the substrate, the first bank layer including an opening defining an emission area of the at least one display element, and wherein the overcoat layer further comprises a plurality of second grooves disposed in the display area and overlapping the first bank layer in a plan view.

The color conversion-transmissive layer may include a color converter including a plurality of quantum dots and a second bank layer surrounding the color converter, and the plurality of second grooves may overlap the second bank layer in a plan view.

The color filter layer may include a first color filter configured to transmit light of a first color, a second color filter configured to transmit light of a second color, a third color filter configured to transmit light of a third color, and a light-blocking portion partitioning the second color filter and the third color filter, wherein the light-blocking portion may include at least two of a first color layer, a second color layer, and a third color layer respectively, the light blocking portion may comprise materials identical to materials of the first color filter, the second color filter, and the third color filter.

The encapsulation layer may include a first inorganic encapsulation film, a first organic encapsulation layer, and a second inorganic encapsulation layer, which are sequentially stacked on each other, and the color conversion-transmissive layer may be in direct contact with the second inorganic encapsulation layer.

According to one or more embodiments, a display apparatus may include a substrate including a display area and a non-display area surrounding the display area, a display element layer disposed on the substrate and including at least one display element, an encapsulation layer disposed on the display element layer and including at least one inorganic encapsulation layer and at least one organic encapsulation layer, a color filter layer disposed on the encapsulation layer and including a first color filter configured to transmit light of a first color, a second color filter configured to transmit light of a second color, a third color filter configured to transmit light of a third color, and a light-blocking portion partitioning the first color filter, the second color filter, and the third color filter, and an overcoat layer comprised of an organic material and disposed on the color filter layer to cover edges of the color filter layer, the overcoat layer may include a plurality of grooves.

A center width of each of the plurality of grooves may be in a range of about 1 μm to about 100 μm, and the plurality of grooves may expose at least a portion of a top surface of the color filter layer.

The plurality of grooves may comprise a plurality of first grooves in the non-display area and a plurality of second grooves at least partially overlapping the light-blocking portion in the display area.

The light-blocking portion may include a first color layer, a second color layer, and a third color layer that overlap one another, the first color layer, the second color layer, and the third color layer may respectively comprise materials identical to materials of the first color filter, the second color filter, and the third color filter.

A bottom surface of the overcoat layer may include a concave surface corresponding to a convex surface included in a top surface of the color filter layer.

A thickness of the overcoat layer may be in a range of about 3 μm to about 8 μm.

The display apparatus may further include a sub capping layer extending from the display area to the non-display area, the sub capping layer may be disposed in the plurality of grooves.

The above and other aspects, features, and advantages will be more apparent from the following descriptions, claims, and the accompanying drawings.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a perspective view schematically illustrating a display apparatus according to an embodiment;

FIG. 2 is a schematic cross-sectional view schematically illustrating a display apparatus according to an embodiment;

FIG. 3 illustrates optical layers of a color conversion-transmissive layer shown in FIG. 2;

FIG. 4 is a schematic diagram of an equivalent circuit of a pixel provided in a display apparatus according to an embodiment;

FIG. 5 is a schematic cross-sectional view schematically illustrating a display apparatus according to an embodiment;

FIGS. 6A and 6B are a schematic cross-sectional view and a plan view, respectively, schematically illustrating a portion of a non-display area of a display apparatus according to an embodiment;

FIGS. 7A and 7B are schematic cross-sectional views schematically illustrating a portion of a non-display area of a display apparatus according to an embodiment;

FIG. 8 is a schematic cross-sectional view schematically illustrating a portion of a non-display area of a display apparatus according to an embodiment; and

FIGS. 9A and 9B are a schematic cross-sectional view and a plan view, respectively, schematically illustrating a portion of a display area of a display apparatus according to an embodiment.

### DETAILED DESCRIPTION OF THE EMBODIMENTS

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals and/or reference characters denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another.

For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

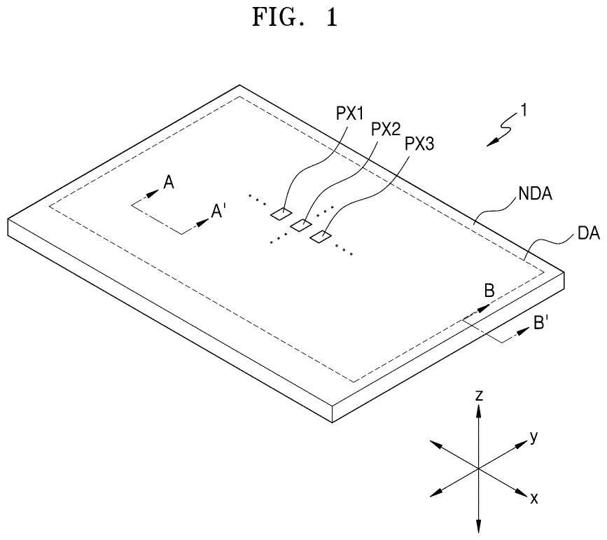

Referring to FIG. 1, a display apparatus 1 may include a display area DA implementing images and a non-display area NDA that does not implement images. The display apparatus 1 may be configured to provide images through arrays of multiple subpixels two-dimensionally arranged in a plan view in the display area DA. The subpixels may be configured to respectively emit light of different colors, and for example, the subpixel may include one of a red subpixel, a green subpixel, and a blue subpixel.

In an embodiment, the subpixels may include a first subpixel PX1, a second subpixel PX2, and a third subpixel PX3, and hereinafter, for convenience of explanation, an embodiment in which the first subpixel PX1 includes a red subpixel, the second subpixel PX2 includes a green subpixel, and the third subpixel PX3 includes a blue subpixel is described.

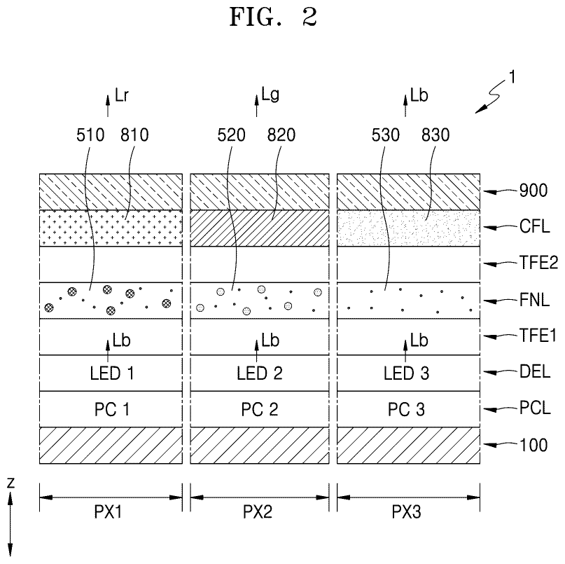

The first subpixel PX1, the second subpixel PX2, and the third subpixel PX3 include areas from which red light Lr (see FIG. 2) green light Lg (see FIG. 2), and blue light Lb (sec FIG. 2) may be emitted, and the display apparatus 1 may be configured to provide images using light emitted from the subpixels.

The non-display area NDA, which is an area where images are not provided, may entirely surround the display area DA. A driver or a main voltage line configured to provide electrical signals or power to pixel circuits may be arranged in the non-display area NDA. The non-display area NDA may include a pad, i.e., an area to which an electronic device or a printed circuit board may be electrically connected.

As shown in FIG. 1, the display area DA may have a polygon shape, including a square shape. For example, the display area DA may include a rectangular shape in which a horizontal length is greater than a vertical length, a rectangular shape in which a horizontal length is less than a vertical length, or a square shape. In other embodiments, the display area DA may have a circular shape, an elliptical shape, or a polygon shape such as a triangle or a pentagon. FIG. 1 illustrates that the display apparatus 1 is a flat panel display apparatus having a flat shape, but the display apparatus 1 may be implemented in various forms such as a flexible display apparatus, a foldable display apparatus, a rollable display apparatus, and the like.

In an embodiment, the display apparatus 1 may include an organic light-emitting display. In other embodiments, the display apparatus 1 may include an inorganic light-emitting display or a quantum-dot light-emitting display. For example, an emission layer of a display element included in the display apparatus I may include an organic material, an inorganic material, quantum dots, an organic material and quantum dots, an inorganic material and quantum dots, or an organic material, an inorganic material, and quantum dots. Hereinafter, for convenience of explanation, an embodiment in which the display apparatus 1 includes an organic light-emitting display apparatus will be described in detail.

FIG. 2 is a schematic cross-sectional view schematically illustrating the display apparatus 1 according to an embodiment.

Referring to FIG. 2, the display apparatus 1 may include a circuit layer PCL on a substrate 100. The circuit layer PCL may include a first subpixel circuit PC1, a second subpixel circuit PC2, and a third subpixel circuit PC3, and insulating layers, and the first subpixel circuit PC1, the second subpixel circuit PC2, and the third subpixel circuit PC3 may each include a thin-film transistor and/or a capacitor. A display element layer DEL may include, as display elements, a first light-emitting diode LED1, a second light-emitting diode LED2, and a third light-emitting diode LED3. The first subpixel circuit PC1, the second subpixel circuit PC2, and the third subpixel circuit PC3 may be electrically connected to the first light-emitting diode LED1, the second light-emitting diode LED2, and the third light-emitting diode LED3 of the display element layer DEL, respectively.

The first light-emitting diode LED1, the second light-emitting diode LED2, and the third light-emitting diode LED3 may include organic light-emitting diodes including organic materials. In an embodiment, the first light-emitting diode LED1, the second light-emitting diode LED2, and the third light-emitting diode LED3 may include inorganic light-emitting diodes including inorganic materials. An inorganic light-emitting diode may include a p-n junction diode including materials based on inorganic semiconductors. Holes and electrons are injected in case that a voltage is applied to the p-n junction diode in a positive direction, and energy generated due to recombination of the holes and electrons may be converted into light energy to emit light of certain colors. The aforementioned inorganic light-emitting diode may have a width from about several to hundreds of micrometers or about several to hundreds of nanometers. In some embodiments, the first light-emitting diode LED1, the second light-emitting diode LED2, and the third light-emitting diode LED3 may include light-emitting diodes including quantum dots. As described above, emission layers of the first light-emitting diode LED1, the second light-emitting diode LED2, and the third light-emitting diode LED3 may include an organic material, an inorganic material, quantum dots, an organic material and quantum dots, or an inorganic material and quantum dots.

The first light-emitting diode LED1, the second light-emitting diode LED2, and the third light-emitting diode LED3 may be configured to emit light of a same color. For example, the first light-emitting diode LED1, the second light-emitting diode LED2, and the third light-emitting diode LED3 may be configured to emit blue light Lb. However, the disclosure is not limited thereto. In other embodiments, the first light-emitting diode LED1, the second light-emitting diode LED2, and the third light-emitting diode LED3 may be configured to emit light of different colors. The light (e.g., the blue light Lb) emitted from the first light-emitting diode LED1, the second light-emitting diode LED2, and the third light-emitting diode LED3 may pass through the color conversion-transmissive layer FNL via an encapsulation layer TFE1 on the display element layer DEL.

The color conversion-transmissive layer FNL may include optical layers configured to transmit the light (e.g., the blue light Lb) emitted from the display element layer DEL with or without color conversion. For example, the color conversion-transmissive layer FNL may include color converters configured to convert the light (e.g., the blue light Lb) emitted from the display element layer DEL into light of other colors, and a transmitter configured to transmit the light (e.g., the blue light Lb) emitted from the display element layer DEL without color conversion. The color conversion-transmissive layer FNL may include a color converter 500 that may include a first color converter 510 corresponding to the first subpixel PX1, a second color converter 520 corresponding to the second subpixel PX2, and a transmitter 530 corresponding to the third subpixel PX3. The first color converter 510 may be configured to convert the blue light Lb into red light Lr, and the second color converter 520 may be configured to convert the blue light Lb into green light Lg. The transmitter 530 may be configured to transmit the blue light Lb without conversion.

A color filter layer CFL may be disposed above the color conversion-transmissive layer FNL. An upper encapsulation layer TFE2 may be disposed between the color conversion-transmissive layer FNL and the color filter layer CFL. The color filter layers CFL may include a first color filter 810, a second color filter 820, and a third color filter 830 respectively having different colors. In an embodiment, the first color filter 810 may include a red color filter, the second color filter 820 may include a green color filter, and the third color filter 830 may include a blue color filter.

Color purity of each of the light color-converted and converted through the color conversion-transmissive layer FNL may be improved through the first color filter 810, the second color filter 820, and the third color filter 830. The color filter layer CFL may be configured to prevent or minimize reflection of external light (e.g., light incident to the display apparatus 1 from outside the display apparatus 1) and recognition of the light by a user.

An overcoat layer 900 may be disposed on the color filter layer CFL. The overcoat layer 900 may include an organic material. For example, the overcoat layer 900 may include a light-transparent organic material, e.g., an acryl-based resin.

In an embodiment, after the color conversion-transmissive layer FNL, the upper encapsulation layer TFE2, and the color filter layer CFL have been sequentially formed on the encapsulation layer TFE1, the overcoat layer 900 may be formed by being coated (e.g., directly coated) and cured on the color filter layer CFL. In some embodiments, other optical films, e.g., an anti-reflection (AR) film, may be disposed on the overcoat layer 900. In some embodiments, a window (not shown) may be further disposed on the overcoat layer 900.

The display apparatus 1 having the aforementioned structure may include an electronic device configured to display videos or still images, e.g., televisions, billboard charts, theater screens, monitors, tablet personal computers, and notebooks.

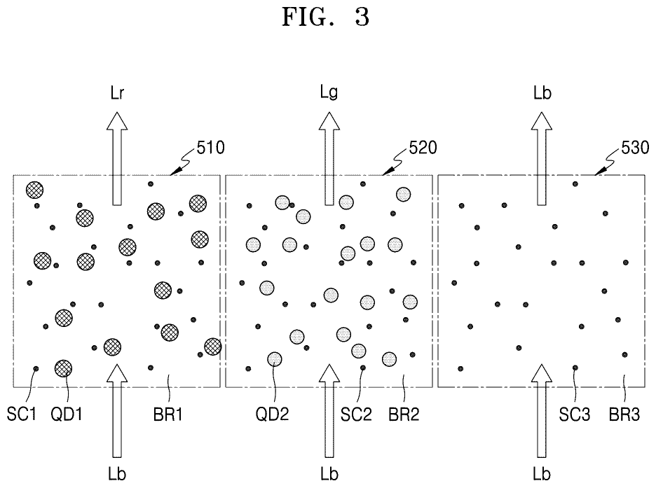

FIG. 3 illustrates the optical layers of the color conversion-transmissive layer FNL shown in FIG. 2.

Referring to FIG. 3, the first color converter 510 may be configured to convert the blue light Lb, which is incident to the first color converter 510, into red light Lr. As shown in FIG. 3, the first color converter 510 may include a first photosensitive polymer BR1 and first quantum dots QD1 and first scattering particles CS1 distributed in the first photosensitive polymer BR1.

The first quantum dots QD1 may be excited due to the blue light Lb and may isotropically emit the red light Lr having a wavelength greater than a wavelength of the blue light Lb. The first photosensitive polymer BR1 may include a transparent organic material.

The first scattering particles SC1 may scatter the red light Lb not absorbed into the first quantum dots QD1 to have a greater amount of the first quantum dots QD1 excited, thereby increasing color conversion efficiency. The first scattering particles SC1 may include, for example, titanium oxide (TiO₂), metal particles, and the like. The first quantum dots QD1 may be selected from among a Group II-VI compound, a Group III-V compound, a Group IV-VI compound, a Group IV element, a Group IV compound, and combinations thereof.

The second color converter 520 may be configured to convert the blue light Lb, which is incident to the second color converter 520, into green light Lg. As shown in FIG. 3, the second color converter 520 may include a second photosensitive polymer BR2, and second quantum dots QD2 and second scattering particles SC2 distributed in the second photosensitive polymer BR2.

The second quantum dots QD2 may be excited due to the blue light Lb and may isotropically emit the green light Lg having a wavelength greater than the wavelength of the blue light Lb. The second photosensitive polymer BR2 may include a transparent organic material.

The second scattering particles SC2 may scatter the blue light Lb not absorbed into the second quantum dots QD2 to have a greater amount of the second quantum dots QD2 excited, thereby increasing color conversion efficiency. The second scattering particles SC2 may include, for example, titanium oxide (TiO₂), metal particles, and the like. The second quantum dots QD2 may be selected from among a Group II-VI compound, a Group III-V compound, a Group IV-VI compound, a Group IV element, a Group IV compound, and combinations thereof.

For example, the first quantum dots QD1 and the second quantum dots QD2 may include same materials. A size of the second quantum dots QD2 may be greater than a size of the first quantum dots QD1.

The transmitter 530 may be configured to transmit the blue light Lb without conversion of the blue light Lb incident to the transmitter 530. As shown in FIG. 3, the transmitter 530 may include a third photosensitive polymer BR3 in which third scattering particles SC3 are distributed. The third photosensitive polymer BR3 may include a transparent organic material, e.g., a silicon resin, an epoxy resin, and the like, and may include a material identical to a material of the first photosensitive polymer BR1 and the second photosensitive polymer BR2. The third scattering particles SC3 may scatter and emit the blue light Lb, and may include a material identical to the material of the first scattering particles SC1 and the second scattering particles SC2.

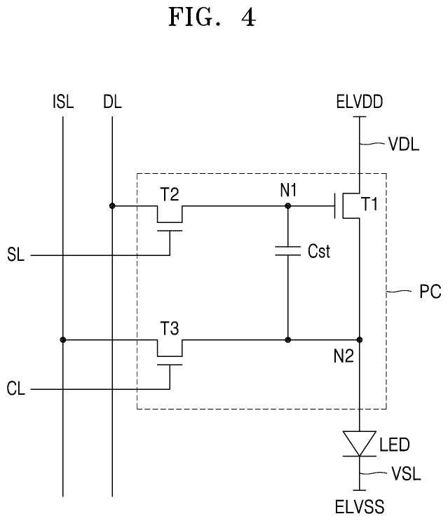

FIG. 4 is a schematic diagram of an equivalent circuit of a light-emitting diode LED included in the display apparatus 1 according to an embodiment and a subpixel circuit PC electrically connected to the light-emitting diodes LED. The subpixel circuit PC shown in FIG. 4 may correspond to each of the first subpixel circuit PC1, the second subpixel circuit PC2, and the third subpixel circuit PC3 described above with reference to FIG. 2, and the light-emitting diode LED shown in FIG. 4 may correspond to each of the first light-emitting diode LED1, the second light-emitting diode LED2, and the third light-emitting diode LED3 described above with reference to FIG. 2.

Referring to FIG. 4, a subpixel electrode (e.g., an anode) of a light-emitting diode, e.g., the light-emitting diode LED, may be electrically connected to the subpixel circuit PC, and a counter electrode (e.g., a cathode) of the light-emitting diode LED may be electrically connected to a common voltage line VSL, which is configured to provide a common voltage ELVSS, or an auxiliary wiring (not shown). The light-emitting diode LED may be configured to emit light with luminance corresponding to an amount of current provided from the subpixel circuit PC.

The subpixel circuit PC may be configured to control an amount of a current flowing from a driving voltage ELVDD to the common voltage ELVSS via the light-emitting diode LED in response to a data signal. The subpixel circuit PC may include a first thin-film transistor T1, a second thin-film transistor T2, a third thin-film transistor T3, and a storage capacitor Cst.

Each of the first thin-film transistor T1, the second thin-film transistor T2, and the third thin-film transistor T3 may include an oxide semiconductor transistor, which includes a semiconductor layer including an oxide semiconductor, or a silicon semiconductor transistor including a semiconductor layer including polysilicon. According to types of the thin-film transistors, a first electrode may include one of a source electrode and a drain electrode, and a second electrode may include another one of the source electrode and the drain electrode.

The first thin-film transistor T1 may include a driving thin-film transistor. A first electrode of the first thin-film transistor T1 may be electrically connected to a driving voltage line VDL configured to provide a driving voltage ELVDD, and a second electrode may be electrically connected a subpixel electrode of the light-emitting diode LED. A gate electrode of the thin-film transistor T1 may be electrically connected to a first node N1. The first thin-film transistor T1 may be configured to control an amount of a current flowing from the driving voltage ELVDD through the light-emitting diode LED in response to a voltage of the first node N1.

The second thin-film transistor T2 may include a switching thin-film transistor. A first electrode of the second thin-film transistor T2 may be electrically connected to a data line DL, and a second electrode may be electrically connected to the first node N1. A gate electrode of the second thin-film transistor T2 may be electrically connected to a scan line SL. The second thin-film transistor T2 may be turned on in case that a scan signal is provided from the scan line SL and may electrically connect the data line DL and the first node N1.

The third thin-film transistor T3 may include an initialization thin-film transistor and/or a sensing thin-film transistor. A first electrode of the third thin-film transistor T3 may be electrically connected to a second node N2, and a second electrode may be electrically connected to a sensing line ISL. A gate electrode of the third thin-film transistor T3 may be electrically connected to a control line CL.

The storage capacitor Cst may be electrically connected between the first node N1 and the second node N2. For example, a first capacitor electrode of the storage capacitor Cst may be electrically connected to the gate electrode of the first thin-film transistor T1, and a second capacitor electrode of the storage capacitor Cst may be electrically connected to the subpixel electrode of the light-emitting diode LED.

Although FIG. 4 illustrates the first thin-film transistor T1, the second thin-film transistor T2, and the third thin-film transistor T3 as NMOS transistors, the disclosure is not limited thereto. For example, at least one of the first thin-film transistor T1, the second thin-film transistor T2, and the third thin-film transistor T3 may include a PMOS transistor.

Although FIG. 4 illustrates three thin-film transistors, the disclosure is not limited thereto. The subpixel circuit PC may include four or more thin-film transistors.

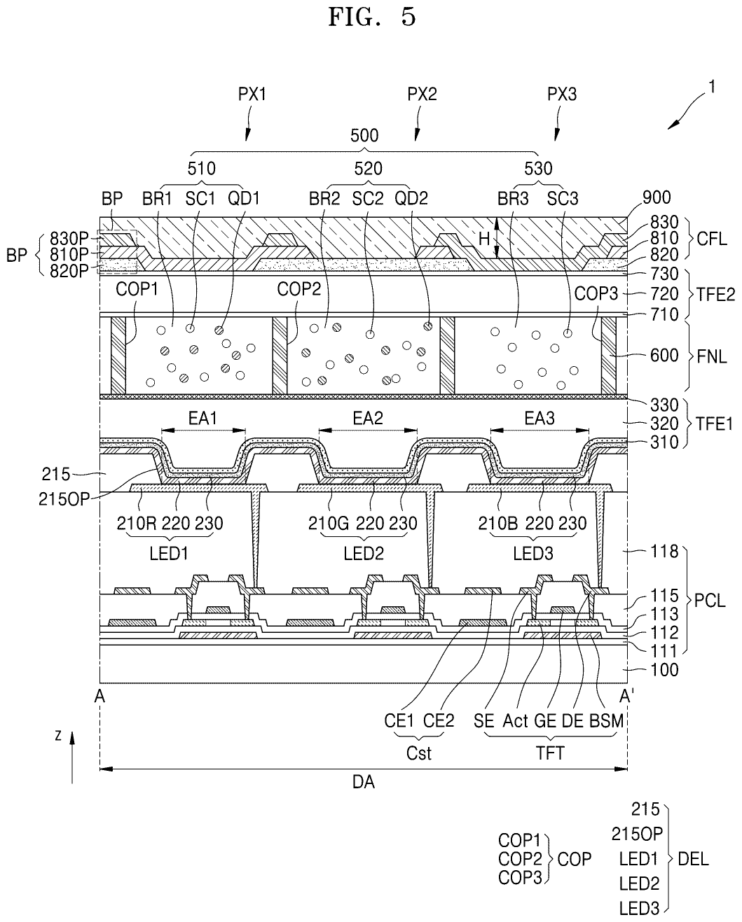

FIG. 5 is a schematic cross-sectional view schematically illustrating the display apparatus 1 according to an embodiment. Referring to FIG. 5, the display apparatus 1 may include the first subpixel PX1, the second subpixel PX2, and the third subpixel PX3 respectively emitting light of different colors. For example, the first subpixel PX1 may implement the red light Lr, the second subpixel PX2 may implement the green light Lg, and the third subpixel PX3 may implement the blue light Lb.

The display apparatus 1 may include a stack structure including the substrate 100, the circuit layer PCL, the display element layer DEL, the color conversion-transmissive layer FNL, and the color filter layer CFL sequentially stacked on the substrate 100. The display element layer DEL may include the first light-emitting diode LED1, the second light-emitting diode LED2, and the third light-emitting diode LED3 electrically connected to the subpixel circuits of the circuit layer PCL. The circuit layer PCL may include multiple subpixel circuits respectively corresponding to the first subpixel circuit PX1, the second subpixel circuit PX2, and the third subpixel circuit PX3. The subpixel circuit may include multiple thin-film transistors TFT and the storage capacitor Cst as described above with reference to FIG. 4. For example, the thin-film transistor TFT may include the driving thin-film transistor T1 (see FIG. 4).

The substrate 100 may include for example glass or a polymer resin. The polymer resin may include at least one of polyethersulfone, polyarylate, polyether imide, polyethylene naphthalate, polyethylene terephthalate, polyphenylene sulfide, polyimide, polycarbonate, cellulose triacetate, cellulose acetate propionate, and the like. The substrate 100 may have a single-layered or multi-layered structure including the aforementioned materials. In an embodiment, the substrate 100 may include a structure including an organic material/an inorganic material/an organic material.

The circuit layer PCL may be disposed on the substrate 100. FIG. 5 illustrates that the circuit layer PCL includes the thin-film transistor TFT, the storage capacitor Cst, a first buffer layer 111, a second buffer layer 112, a gate insulating layer 113, an interlayer insulating layer 115, and a planarization layer 118 disposed under or/and on the components.

The first buffer layer 111 and the second buffer layer 112 may reduce or prevent permeation of foreign material, moisture, or external air from under the substrate 100. The first buffer layer 111 and the second buffer layer 112 may include an inorganic insulating material such as silicon nitride, silicon oxynitride, and silicon oxide, and may include a single layer or multiple layers including the aforementioned inorganic insulating materials.

A bias electrode BSM may be disposed on the first buffer layer 111 to correspond to the thin-film transistor TFT. In an embodiment, a voltage may be applied to the bias electrode BSM. The bias electrode BSM may prevent external light from reaching the semiconductor layer Act. Accordingly, characteristics of the thin-film transistor TFT may be stabilized. In some embodiments, the bias electrode BSM may be omitted.

A semiconductor layer Act may be disposed on the second buffer layer 112. The semiconductor layer Act may include amorphous silicon or polysilicon. In other embodiments, the semiconductor layer Act may include an oxide of at least one material selected from indium (In), gallium (Ga), tin (Sn), zirconium (Zr), vanadium (V), hafnium (Hf), cadmium (Cd), germanium (Ge), chromium (Cr), titanium (Ti), aluminum (Al), cesium (Cs), cerium (Ce), and zinc (Zn). In some embodiments, the semiconductor layer Act may include a Zn oxide-based material, e.g., Zn oxide, In—Zn oxide, Ga—In—Zn oxide, and the like. In some embodiments, the semiconductor layer Act may include an In—Ga—Zn—O (IGZO) semiconductor, an In—Sn—Zn—O (ITZO) semiconductor, or an In—Ga—Sn—Zn—O (IGTZO) semiconductor, in which a metal such as In, Ga, and Sn is included in addition to ZnO. The semiconductor layer Act may include a channel area, and a source area and a drain area respectively arranged at two sides of the channel area. The gate electrode GE may overlap the channel area of the semiconductor layer Act.

The gate electrode GE may include a low-resistance metal material. The gate electrode GE may include a conductive material such as molybdenum (Mo), aluminum (Al), copper (Cu), titanium (Ti), and the like, and may include a single layer or multiple layers including the aforementioned material.

The gate insulating layer 113 may be disposed between the semiconductor layer Act and the gate electrode GE. The gate insulating layer 113 may include an inorganic insulating material such as silicon oxide, silicon nitride, silicon oxynitride, aluminum oxide, titanium oxide, tantalum oxide, hafnium oxide, or zinc oxide.

The first electrode CE1 of the storage capacitor Cst may be disposed on a same layer as the gate electrode GE. The first electrode CE1 and the gate electrode GE may include a same material. Although FIG. 5 illustrates that the gate electrode GE of the thin-film transistor TFT and the first electrode CE1 of the storage capacitor Cst are separately arranged, in an embodiment, the storage capacitor Cst may overlap the thin-film transistor TFT. The gate electrode GE of the thin-film transistor TFT may perform functions as the first electrode CE1 of the storage capacitor Cst.

The interlayer insulating layer 115 may be provided to cover the gate electrode GE. The interlayer insulating layer 115 may include an inorganic insulating material such as silicon oxide, silicon nitride, silicon oxynitride, aluminum oxide, titanium oxide, tantalum oxide, hafnium oxide, zinc oxide, or a combination thereof.

A second electrode CE2 of the storage capacitor Cst, the source electrode SE, the drain electrode DE, and the like may be disposed on the interlayer insulating layer 115.

The second electrode CE2 of the storage capacitor Cst, the source electrode SE, and the drain electrode DE may include a conductive material including Mo, Al, Cu, Ti, and the like, and may include a single layer or multiple layers including the aforementioned materials. For example, the second electrode CE2 of the storage capacitor Cst, the second electrode SE, and the drain electrode DE may have a multi-layered structure including Ti/Al/Ti. The source electrode SE and the drain electrode DE may contact the source area or the drain area of the semiconductor layer Act through contact holes.

The second electrode CE2 of the storage capacitor Cst may overlap the first electrode CE1 with the interlayer insulating layer 115 therebetween, and may constitute the storage capacitor Cst. The interlayer insulating layer 115 may function as a dielectric layer of the storage capacitor Cst.

The planarization layer 118 may be arranged to cover the second electrode CE2 of the storage capacitor Cst, the source electrode SE, and the drain electrode DE. The planarization layer 118 may include a single layer or multiple layers of a film including an organic material, and may provide a planar top surface. The planarization layer 118 may include a general-purpose polymer such as benzocyclobutene (BCB), polyimide, hexamethyldisiloxane (HMDSO), polymethylmethacrylate (PMMA), or polystyrene (PS), a polymer derivative having a phenol group, an acryl-based polymer, an imide-based polymer, an aryl ether-based polymer, an amide-based polymer, a fluoride-based polymer, a p-xylene-based polymer, a vinyl alcohol-based polymer, and blends thereof.

The display element layer DEL may be disposed on the circuit layer PCL having the aforementioned structure. The display element layer DEL may include, as display elements, the first light-emitting diode LED1, the second light-emitting diode LED2, and the third light-emitting diode LED3, which are organic light-emitting diodes. The first light-emitting diode LED1, the second light-emitting diode LED2, and the third light-emitting diode LED3 may respectively include a first subpixel electrode 210R, a second subpixel electrode 210G, and a third subpixel electrode 210B. In an embodiment, the first light-emitting diode LED1, the second light-emitting diode LED2, and the third light-emitting diode LED3 may include an emission layer 220 and a counter electrode 230 in common.

The first subpixel electrode 210R, the second subpixel electrode 210G, and the third subpixel electrode 210B may include a (semi) transparent electrode or a reflective electrode. In some embodiments, the first subpixel electrode 210R, the second subpixel electrode 210G, and the third subpixel electrode 210B may include a conductive oxide such as indium tin oxide (ITO), indium zinc oxide (IZO), zinc oxide (ZnO), indium oxide (In₂O₃), indium gallium oxide (IGO), aluminum zinc oxide (AZO), or a combination thereof. In an embodiment, the first subpixel electrode 210R, the second subpixel electrode 210G, and the third subpixel electrode 210B may include a reflective film including silver (Ag), magnesium (Mg), aluminum (Al), platinum (Pt), palladium (Pd), gold (Au), nickel (Ni), neodymium (Nd), iridium (Ir), chromium (Cr), compounds thereof, or combinations thereof. As another example, a film including ITO, IZO, ZnO, or In₂O₃ may be further provided on/under the aforementioned reflective film. For example, the first subpixel electrode 210R, the second subpixel electrode 210G, and the third subpixel electrode 210B may be provided as ITO/Ag/ITO.

A first bank layer 215 may be disposed on the planarization layer 118. The first bank layer 215 may include an opening 215OP exposing a center portion of each of the first subpixel electrode 210R, the second subpixel electrode 210G, and the third subpixel electrode 210B. The first bank layer 215 may cover edges of the first subpixel electrode 210R, the second subpixel electrode 210G, and the third subpixel electrode 210B. The first bank layer 215 may prevent generation of arcs and the like at the edges of the first subpixel electrode 210R, the second subpixel electrode 210G, and the third subpixel electrode 210B by increasing distances from the counter electrode 230 to the edges of each of the first subpixel electrode 210R, the second subpixel electrode 210G, and the third subpixel electrode 210B.

The first bank layer 215 may include one or more organic insulating materials selected from among a group including polyimide, polyamide, an acryl resin, BCB, and a phenol resin.

The emission layer 220 of each of the first light-emitting diode LED1, the second light-emitting diode LED2, and the third light-emitting diode LED3 may include an organic material including a fluorescent or phosphorescent material emitting light of red, green, blue, or white. The emission layer 220 may include a low-molecular organic material or a high-molecular organic material, and a functional layer such as a hole transport layer (HTL), a hole injection layer (HIL), an electron transport layer (ETL), and an electron injection layer (EIL) may be selectively further disposed under and above the emission layer 220. As shown in FIG. 5, the emission layer 220 may be integrally formed over the first subpixel electrode 210R, the second subpixel electrode 210G, and the third subpixel electrode 210B, the disclosure is not limited thereto. In some embodiments, the emission layer 220 may also include a layer patterned to correspond to each of the first subpixel electrode 210R, the second subpixel electrode 210G, and the third subpixel electrode 210B. In any occasion, the emission layer 220 may include a first color emission layer, a second color emission layer, and a third color emission layer that emits light of a first wavelength band, a second wavelength band and a third wavelength band respectively. The third color emission layer may be configured to emit light of a third wavelength band, e.g., blue light. In an embodiment, the emission layer 220 may be configured to emit light of a wavelength band in a range of about 450 nm to about 495 nm.

The counter electrode 230 may be disposed on the emission layer 220 to correspond to the first subpixel electrode 210R, the second subpixel electrode 210G, and the third subpixel electrode 210B. The counter electrode 230 may be integrally formed over the first subpixel electrode 210R, the second subpixel electrode 210G, and the third subpixel electrode 210B. In an embodiment, the counter electrode 230 may include a conductive material having a small work function. For example, the counter electrode 230 may include a semitransparent layer such as Ag, Mg, Al, Pt, Pd, Au, Ni, Nd, Ir, Cr, Li, Ca, alloys thereof, or a combination thereof. As another example, the counter electrode 230 may further include a layer such as including ITO, IZO, ZnO, In₂O₃, or the like on the semitransparent layer including the aforementioned materials.

The first emission area EA1, the second emission area EA2, and the third emission area EA3 may respectively correspond to the first subpixel PX1, the second subpixel PX2, and the third subpixel PX3. The first emission area EA1, the second emission area EA2, and the third emission area EA3 may respectively include an area in which light generated from the first light-emitting diode LED1, the second light-emitting diode LED2, and the third light-emitting diode LED3 is emitted outside. The first emission area EA1 may be defined as a portion of the first subpixel electrode 210R that is exposed through the opening 215OP of the first bank layer 215. The second emission area EA2 may be defined as a portion of the second subpixel electrode 210G that is exposed through the opening 215OP of the first bank layer 215. The third emission area EA3 may be defined as a portion of the third subpixel electrode 210B that is exposed through the opening 215OP of the first bank layer 215. In other words, each of the first emission area EA1, the second emission area EA2, and the third emission area EA3 may be defined by each of the openings 215OP of the first bank layer 215.

The first emission area EA1, the second emission area EA2, and the third emission area EA3 may be apart from one another. Areas of the display area DA, except the first emission area EA1, the second emission area EA2, and the third emission area EA3 may include non-emission areas. The first emission area EA1, the second emission area EA2, and the third emission area EA3 may be distinguished from one another by the non-emission areas.

A spacer for preventing a mask from being stamped may be further provided on the first bank layer 215. In an embodiment, the spacer and the first bank layer 215 may be integral with each other. For example, the spacer and the first bank layer 215 may be simultaneously formed in a same process, using for example a halftone mask.

The encapsulation layer TFE1 may be arranged to cover the display element layer DEL. The first light-emitting diode LED1, the second light-emitting diode LED2, and the third light-emitting diode LED3, which may be readily damaged due to moisture or oxygen from outside, may be covered and protected by the encapsulation layer TFE1. The encapsulation layer TFE1 may cover the display area DA and extend to the outside of the display area DA. The thin-film encapsulation layer TFE1 may include at least one organic encapsulation layer and at least one inorganic encapsulation layer. For example, the thin-film encapsulation layer TFE1 may include a first inorganic encapsulation layer 310, a first organic encapsulation layer 320, and a second inorganic encapsulation layer 330 that are sequentially stacked on each other.

Each of the first inorganic encapsulation layer 310 and the second inorganic encapsulation layer 330 may include one or more inorganic materials such as aluminum oxide, titanium oxide, tantalum oxide, hafnium oxide, zinc oxide, silicon oxide, silicon nitride, sand silicon oxynitride, or a combination thereof. The first organic encapsulation layer 320 may include a polymer-based material. The polymer-based material may include an acryl-based resin, an epoxy-based resin, polyimide, polyethylene, the like, or a combination thereof. In an embodiment, the first organic encapsulation layer 320 may include acrylate. The first organic encapsulation layer 320 may be formed by curing a monomer or by coating with a polymer.

The encapsulation layer TFE1, which includes the aforementioned multi-layered structure, may prevent propagation of cracks between the first inorganic encapsulation layer 310 and the first organic encapsulation layer 320 or between the first organic encapsulation layer 320 and the second inorganic encapsulation layer 330 in case that the cracks are generated in the encapsulation layer TFE1. The encapsulation layer TFE1 may prevent or minimize forming of a path through which moisture or oxygen from outside may permeate into the display area DA.

In some embodiments, other layers such as a capping layer may be further disposed between the first inorganic encapsulation layer 310 and the counter electrode 230.

The color conversion-transmissive layer FNL may be disposed on the encapsulation layer TFE1. The color conversion-transmissive layer FNL may include the first color converter 510, the second color converter 520, the transmitter 530, and a second bank layer 600. The color conversion-transmissive layer FNL may contact (e.g., directly contact) a second inorganic encapsulation layer 330 of the encapsulation layer TFE1.

The second bank layer 600 may be disposed on the encapsulation layer TFE1. The second bank layer 600 may include an organic material or an inorganic material. For example, the second bank layer 600 may include an inorganic material such as silicon oxide, silicon nitride, and/or silicon oxynitride. According to occasion, the second bank layer 600 may further include a light-blocking material to function as a light-blocking layer. The light-blocking material may include, for example, at least one of a black pigment, a black dye, black particles, or metal particles.

In the second bank layer 600, openings COP may be defined by partitions. A first opening COP1 of the second bank layer 600 may correspond to the opening 215OP exposing the first subpixel electrode 210R of the first bank layer 215, a second opening COP2 of the second bank layer 600 may correspond to the opening 215OP exposing the second subpixel electrode 210G of the first bank layer 215, and a third opening COP3 of the second bank layer 600 may correspond to the opening 215OP exposing the third subpixel electrode 210B of the first bank layer 215. For example, when seen in a direction (the z axis direction) perpendicular to the substrate 100, the first opening COP1 of the second bank layer 600 may overlap the opening 215OP exposing the first subpixel electrode 210R of the first bank layer 215, the second opening COP2 of the second bank layer 600 may overlap the opening 215OP exposing the second subpixel electrode 210G of the first bank layer 215, and the third opening COP3 of the second bank layer 600 may overlap the opening 215OP exposing the third subpixel electrode 210B of the first bank layer 215. Partitions may be arranged among the first opening COP1, the second opening COP2, and the third opening COP3 of the second bank layer 600.

The first color converter 510, the second color converter 520, and the transmitter 530 may fill the openings COP of the second bank layer 600. In an embodiment, the first color converter 510, the second color converter 520, and the transmitter 530 may include at least one of quantum dots and scattering particles.

The first color converter 510 may fill the first opening COP1 of the second bank layer 600. The first color converter 510 may overlap the first emission area EA1. The first subpixel PX1 may include the first light-emitting diode LED1 and the first color converter 510.

The first color converter 510 may be configured to convert light of a third wavelength band, which is generated in the emission layer 220 on the first subpixel electrode 210R, into light of a first wavelength band. The first color converter 510 may be configured to convert blue light into red light. For example, in case that light of a wavelength from about 450 nm to about 495 nm is generated in the emission layer 220 on the first subpixel electrode 210R, the first color converter 510 may convert the light into light of a wavelength in a range of about 630 nm to about 780 nm. Accordingly, the light of the wavelength in a range of about 630 nm to about 780 nm may be emitted outside from the first subpixel PX1.

The first color converter 510 may include the first photosensitive polymer BR1, and the first quantum dots QD1 and the first scattering particles SCI distributed in the first photosensitive polymer BR1.

The second color converter 520 may fill the second opening COP2 of the second bank layer 600. The second color converter 520 may overlap the second emission area EA2. The second subpixel PX2 may include the second light-emitting diode LED2 and the second color converter 520.

The second color converter 520 may be configured to convert light of a third wavelength band, which is generated in the emission layer 220 on the second subpixel electrode 210G, into light of a second wavelength band. The second color converter 520 may be configured to convert blue light into green light. For example, in case that light of a wavelength in a range of about 450 nm to about 495 nm is generated in the emission layer 220 on the second subpixel electrode 210G, the second color converter 520 may convert the light into light of a wavelength from about 495 nm to about 570 nm. Accordingly, the light of the wavelength in a range of about 495 nm to about 570 nm may be emitted outside from the second subpixel PX2.

The second color converter 520 may include the second photosensitive polymer BR2, and the second quantum dots QD2 and the second scattering particles SC2 distributed in the second photosensitive polymer BR2.

The transmitter 530 may fill the third opening COP3 in the second bank layer 600. The transmitter 530 may overlap the third emission area EA3. The third subpixel PX3 may include the third light-emitting diode LED3 and the transmitter 530.

The transmitter 530 may be configured to emit the light, which is generated in the emission layer 220 on the third subpixel electrode 210B to the outside without wavelength conversion. The transmitter 530 may be configured to transmit the blue light without conversion. For example, in case that light of the wavelength band in a range of about 450 nm to about 495 nm is generated in the emission layer 220 on the third subpixel electrode 210B, the transmitter 530 may emit the light to the outside without color conversion.

The transmitter 530 may include the third photosensitive polymer BR3 in which the third scattering particles SC3 are distributed. In an embodiment, the transmitter 530 may not include quantum dots.

At least one of the first quantum dots QD1 and the second quantum dots QD2 may include a semiconductor material such as cadmium sulfide (CdS), cadmium telluride (CdTe), zinc sulfide (ZnS), indium phosphide (InO), the like, or a combination thereof. The quantum dots may have a size of several nanometers, and a wavelength of light after conversion may differ according to the size of the quantum dots.

In an embodiment, a core of the quantum dots may be selected from among a Group II-VI compound, a Group III-V compound, a Group IV-VI compound, a Group IV element, a Group IV compound, and combinations thereof.

The Group II-VI compound may be selected from among a two-element compound selected from a group including CdSe, CdTe, ZnS, ZnSe, ZnTe, ZnO, HgS, HgSe, HgTe, MgSe, MgS and mixtures thereof; a three-element compound selected from a group including AgInS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSc, MgZnS, and mixtures thereof; and a four-element compound selected from a group including HgZnTeS, CdZnSeS, CdZnSeTe, CdZnSTe, CdHgSeS, CdHgSeTe, CdHgSTe, HgZnSeS, HgZnSeTe, HgZnSTe, and mixtures thereof.

The Group III-V compound may be selected from among a two-element compound selected from a group including GaN, GaP, GaAs, GaSb, AlN, AlP, AlAs, AlSb, InN, InP, InAs, InSb, and mixtures thereof; a three-element compound selected from a group including GaNP, GaNAs, GaNSb, GaPAs, GaPSb, AlNP, AlNAs, AlNSb, AlPAs, AlPSb, InGaP, InNP, InNAs, InNSb, InPAs, InPSb, GaAlNP, and mixtures thereof; and a four-element compound selected from a group including GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and mixtures thereof.

The Group IV-VI compound may be selected from among a two-element compound selected from a group including SnS, SnSe, SnTe, PbS, PbSe, PbTe, and mixtures thereof; a three-element selected from a group including SnSeS, SnSeTe, SnSTe, PbSeS, PbSeTe, PbSTe, SnPbS, SnPbSe, SnPbTe, and mixtures thereof; and a four-element compound selected from a group including SnPbSSe, SnPbSeTe, SnPbSTe, and mixtures thereof. The Group IV element may be selected from a group including Si, Ge, and a mixture thereof. The Group IV compound may include a two-element compound selected from a group including SiC, SiGe, and a mixture thereof.

Each of the elements included in a multi-clement compound such as the two-element compound, the three-element compound, and the four-element compound may exist in particles in a uniform or non-uniform concentration. The quantum dots may have a core/shell structure in which one quantum dot surrounds another quantum dot. An interface between the core and the shell may have a concentration gradient in which a concentration of an element in the shell decreases toward a center.

In some embodiments, the quantum dots may have a core-shell structure including the core and the shell surrounding the core. The shell of the quantum dot may function as a protective layer for preventing chemical denaturation of the core and maintain the characteristics of the semiconductor and/or a charging layer for granting electrophoretic characteristics to the quantum dot. The shell may include a single layer or multiple layers. An interface between the core and the shell may have a concentration gradient in which a concentration of an element in the shell decreases toward a center. Examples of the shell of the quantum dots may include an oxide of a metal or a non-metal, a semiconductor compound, or combinations thereof.

For example, the oxide of a metal or a non-metal may include a two-element compound such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, or the like, a three-element compound such as MgAl₂O₄, CoFe₂O₄, NiFe₂O₄, CoMn₂O₄, or the like, or arbitrary combinations thereof.

An example of the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, AlAs, AlP, AlSb, and the like, but the disclosure is not limited thereto.

In an embodiment, the quantum dots may each have a full width of half maximum (FWHM) of an emission wavelength spectrum about 45 nm or less, particularly about 40 nm or less, more particularly about 30 nm or less, and color purity or color reproducibility may be improved in the aforementioned range. The light emitted through the quantum dots may be emitted in every direction, and therefore, a viewing angle of the light may be improved.

Furthermore, although not specifically limited, the form of the quantum dots may include shapes generally used in the technical field, more particularly, nanowires, nanofibers, nano platelet particles having a spherical shape, a pyramid shape, a multi-arm shape, or a cubic shape.

The quantum dots may adjust the color of emitted light according to the size of the particles, and accordingly, the quantum dots may emit various colors of light, e.g., blue, red, and green.

The first scattering particles SC1, the second scattering particles SC2, and the third scattering particles SC3 may scatter the light such that a greater amount of light is emitted. The first scattering particles SC1, the second scattering particles SC2, and the third scattering particles SC3 may increase emission efficiency. At least one of the first scattering particles SC1, the second scattering particles SC2, and the third scattering particles SC3 may include any material from between a metal or a metal oxide to uniformly scatter the light. For example, at least one of the first scattering particles SC1, the second scattering particles SC2, and the third scattering particles SC3 may include at least one of TiO₂, ZrO₂, Al₂O₃, In₂O₃, ZnO, SnO₂, Sb₂O₃, and ITO. At least one of the first scattering particles SC1, the second scattering particles SC2, and the third scattering particles SC3 may have a refractive index of about 1.5 or greater. Accordingly, emission efficiency of the color conversion-transmissive layer FNL may be improved. In some embodiment, at least one of the first scattering particles SC1, the second scattering particles SC2, and the third scattering particles SC3 may be omitted.

The first photosensitive polymer BR1, the second photosensitive polymer BR2, and the third photosensitive polymer BR3 may include a light-transmitting organic material. For example, at least one of the first photosensitive polymer BR1, the second photosensitive polymer BR2, and the third photosensitive polymer BR3 may include a polymer resin such as acryl, BCB, or HMDSO.

The upper encapsulation layer TFE2 may be disposed on the color conversion-transmissive layer FNL. The upper encapsulation layer TFE2 may prevent or minimize damage or contamination of the color conversion-transmissive layer FNL due to permeation of impurities such as moisture and/or air from the outside, and may prevent generation and propagation of cracks due to an external force. The upper encapsulation layer TFE2 may improve the reliability of the display apparatus 1 by enhancing protection of the color conversion-transmissive layer FNL in the display apparatus 1 having a structure in which an upper substrate is not provided and components are stacked on each other on the substrate 100 that is a single substrate.

The upper encapsulation layer TFE2 may cover the display area DA and extend to the outside of the display area DA. The upper encapsulation layer TFE2 may include at least one organic encapsulation layer and at least one inorganic encapsulation layer. For example, the upper encapsulation layer TFE2 may include a third inorganic encapsulation layer 710, a second organic encapsulation layer 720, and a fourth inorganic encapsulation layer 730 sequentially stacked on each other.

The third inorganic encapsulation layer 710 and the fourth inorganic encapsulation layer 730 may include at least one inorganic material from among aluminum oxide, titanium oxide, tantalum oxide, hafnium oxide, zinc oxide, silicon oxide, silicon nitride, and silicon oxynitride. The second organic encapsulation layer 720 may include a polymer-based material. The polymer-based material may include an acryl-based resin, an epoxy-based resin, polyimide, polyethylene, and the like. In an embodiment, the second organic encapsulation layer 720 may include acrylate. The second organic encapsulation layer 720 may be formed by curing a monomer or coating with a polymer. In an embodiment, the upper encapsulation layer TEF2 may be omitted.

A color filter layer CFL may be disposed on the upper encapsulation layer TFE2. In an embodiment, the color filter layer CFL may be formed (e.g., directly formed) on a top surface (a z-axis direction) of the upper encapsulation layer TFE2, and may include a first color filter 810, a second color filter 820, a third color filter 830, and a light-blocking portion BP.

The first color filter 810 may be disposed on the first color converter 510 to correspond to the first subpixel PX1, the second color filter 820 may be disposed on the second color converter 520 to correspond to the second subpixel PX2, and the third color filter 830 may be disposed on the transmitter 530 to correspond to the third subpixel PX3. The first color filter 810, the second color filter 820, and the third color filter 830 may include a photosensitive resin. The first color filter 810, the second color filter 820, and the third color filter 830 may include pigments or dyes each expressing an intrinsic color.

The first color filter 810 may include a color filter configured to transmit light of a first color. For example, the first color filter 810 may be configured to only transmit light of a wavelength in a range of about 630 nm to about 780 nm. The first color filter 810 may include a red pigment or a red dye. The second color filter 820 may include a color filter configured to transmit light of a second color. For example, the second color filter 820 may be configured to only transmit light of a wavelength in a range of about 495 nm to about 570 nm. The second color filter 820 may include a green pigment or a green dye. The third color filter 830 may include a color filter configured to transmit light of a third color. For example, the third color filter 830 may be configured to only transmit light of a wavelength in a range of about 450 nm to about 495 nm. The third color filter 830 may include a blue pigment or a blue dye.

The color filter layer CFL may reduce reflection of external light by the display apparatus 1. For example, in case that external light arrives at the first color filter 810, as described above, only light of a preset wavelength band may be transmitted through the first color filter 810, and light of other wavelength bands may be absorbed into the first color filter 810. Accordingly, among the external light incident to the display apparatus 1, only the light of the preset wavelength band may be transmitted through the first color filter 810, and a portion of the transmitted light may be reflected by the counter electrode 230 and/or the first subpixel electrode 210R under the first color filter 810 and may be emitted again to the outside. The first color filter 810 may be configured to reduce reflection of the external light by having only a portion of the external light, which is incident to a position at which the first subpixel PX1 is located, be reflected to the outside. This description may also be applied to the second color filter 820 and the third color filter 830.

The light-blocking portion BP may be formed by overlapping of at least two color layers selected from among a first color layer 810P, a second color layer 820P, and a third color layer 830P respectively including materials identical to the materials of the first color filter 810, the second color filter 820, and the third color filter 830. The first color layer 810P, the second color layer 820P, and the third color layer 830P may overlap one another in a non-emission area. The first color layer 810P, the second color layer 820P, and the third color layer 830P may be formed at the same time as the first color filter 810, the second color filter 820, and the third color filter 830. Through the aforementioned configuration, the color filter CFL may prevent mixing of colors even without an additional light-blocking member such as a black matrix.

For example, a portion at which the first color layer 810P and the second color layer 820P overlap each other, a portion at which the second color layer 820P and the third color layer 830P overlap each other, a portion at which the first color layer 810P and the third color layer 830P overlap each other, and a portion at which the first color layer 810P, the second color layer 820P, and the third color layer 830P overlap one another each may function as a black matrix. This is because, for example, in case that the first color filter 810 only transmits the light of the wavelength in a range of about 630 nm to about 780 nm and the third color filter 830 only transmits the light of the wavelength in a range of about 450 nm to about 495 nm, light which may be transmitted through both of the first color filter 810 and the third color filter 830 does not theoretically exist in the portion at which the first color filter 810 and the third color filter 830 overlap each other.

The light-blocking portion BP may overlap partitions arranged among openings in the second bank layer 600, e.g., a partition arranged between the first opening COP1 and the second opening COP2, a partition arranged between the second opening COP2 and the third opening COP3, and a partition arranged between the first opening COP1 and the third opening COP3. The first color layer 810P, the second color layer 820P, and the third color layer 830P may respectively include a portion of the first color filter 810, a portion of the second color filter 820, and a portion of the third color filter 830 corresponding to the partitions in the second bank layer 600.

The overcoat layer 900 may be disposed to cover the color filter layer CFL. The overcoat layer 900 may generally cover multiple color filters. The overcoat layer 900 may contact (e.g., directly contact) the color filter layer CFL. The overcoat layer 900 may include an organic layer including an organic material. For example, the overcoat layer 900 may include a light-transmitting organic material, e.g., a polyimide resin, an acryl resin, and a resist material. The overcoat layer 900 may be formed by a wet etch process, such as a slit coating method, a spin coating method, and a dry etch process such as chemical vapor deposition method, vacuum deposition method. The embodiments are not limited to materials and a method of forming thereof.

The overcoat layer 900 may protect the color filter layer CFL and planarize a top surface of the color filter layer CFL. A bottom surface of the overcoat layer 900 may have a concavo-convex structure due to stack structures of the first color filter 810, the second color filter 820, and the third color filter 830 of the color filter layer CFL. The bottom surface of the overcoat layer 900 may have a concave surface corresponding to a convex surface included in the color filter layer CFL. The top surface of the overcoat layer 900 may be generally planar.

A thickness H of the overcoat layer 900 may be greater than a thickness of the color filter layer CFL. The thickness H of the overcoat layer 900 may be in a range of about 3 μm to about 8 μm, or may be about 5 μm. The thickness H of the overcoat layer 900 may indicate a distance from the top surface of the color filter layer CFL to a top surface of the overcoat layer 900 in a direction (a z direction) perpendicular to the substrate 100.

In some embodiments, another layer such as a capping layer may be further disposed on the overcoat layer 900 and/or between the overcoat layer 900 and the color filter layer CFL. The capping layer may include an inorganic material. In some embodiments, the overcoat layer 900 may be covered with a window (not shown).

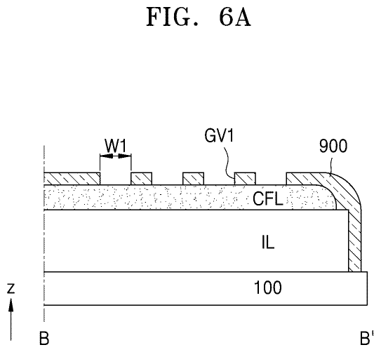

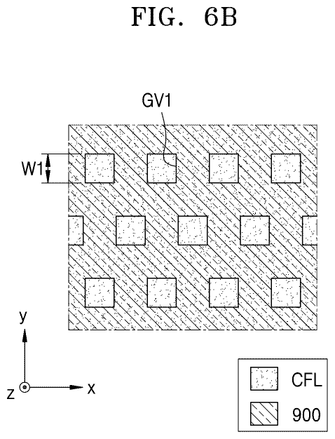

FIGS. 6A and 6B are a schematic cross-sectional view and a plan view schematically illustrating a portion of the non-display area NDA of the display apparatus 1 according to an embodiment, respectively.

The display apparatus 1 may include the substrate 100, a dummy insulating layer IL, the color filter layer CFL, and the overcoat layer 900 arranged in the non-display area NDA. The dummy insulating layer IL may be formed by stacking multiple organic insulating layers and/or multiple inorganic insulating layers. The dummy insulating layer IL may have a structure in which the layers in the display area DA, described with reference to FIG. 5, extend to the non-display area NDA. For example, at least a portion of a first buffer layer 111, a second buffer layer 112, a gate insulating layer 113, an interlayer insulating layer 115, a planarization layer 118, and the first bank layer 215 may extend to the non-display area NDA, and the dummy insulating layer IL may include the first buffer layer 111, the second buffer layer 112, the gate insulating layer 113, the interlayer insulating layer 115, and the planarization layer 118, and the first bank layer 215 stacked on each other and extending to the non-display area NDA.

Referring to FIG. 6A, an edge of the color filter layer CFL may be arranged in the non-display area NDA. For example, an end point of the color filter layer CFL may be in the non-display area NDA. In an embodiment, the color filter CFL in the non-display area NDA may be arranged by stacking portions of the first color filter 810, the second color filter 820, and the third color filter 830.

The overcoat layer 900 may be arranged in the non-display area NDA. The overcoat layer 900 may be arranged to extend from the display area DA to the non-display area NDA, and may be integrally laid in the display area DA and the non-display area NDA. The overcoat layer 900 may cover edges of the layers disposed under the overcoat layer 900. The overcoat layer 900 may cover side surfaces of the layers disposed thereunder. The overcoat layer 900 may cover an edge of the color filter CFL. As shown in FIG. 6A, the overcoat layer 900 may generally cover the edge of the color filter layer CFL and an edge of the dummy insulating layer IL. As another example, the overcoat layer 900 may cover the edge of the color filter layer CFL and an edge of a portion of the insulating layers included in the dummy insulating layer IL.

The display apparatus may be formed by stacking multiple layers on the substrate 100, and an interface between the layers may be torn out due to a tensile stress of each of the layers stacked on each other. Particularly, among the layers stacked on each other, a layer having a greater thickness may have a greater tensile strength, and a tensile strength of an organic film may be greater than a tensile strength of an inorganic film. Compared with a layer arranged in the form of patterns apart from each other in the display apparatus, e.g., an island pattern, a layer arranged all over the display apparatus may occur a greater strength to the display apparatus. When there is a layer having a great tensile strength, an interface having a weak bonding force may be torn out.

Generally, an overcoat layer has a thickness greater than a thickness of a color filter to planarize a top surface of the color filter, and may be provided as an organic film including an organic material. An overcoat layer may be arranged on an entire surface of the display apparatus, instead of being arranged in the form of island patterns corresponding to subpixels, e.g., color filters. Due to strong effect of the overcoat layer, layers under the overcoat layer, as well as the overcoat layer, may be torn out. Tearing of films due to tensile strengths may occur at an outer edge portion of the display apparatus.

According to an embodiment, the overcoat layer 900 may include multiple grooves.

The overcoat layer 900 may include multiple first grooves GV1 arranged in the non-display area NDA. The overcoat layer 900 covers edges of the color filter layer CFL and is arranged all over the substrate 100, and the first grooves GV1 may reduce a tensile strength due to the overcoat layer 900 in the non-display area NDA and prevent tearing of a film in a weak layer occurring from an outer edge portion of the display apparatus. Referring to FIG. 2, after forming all of the circuit layer PCL, the display element layer DEL, the encapsulation layer TFE1, and the color filter layer CFL, the first grooves GV1 may be formed in the overcoat layer 900 formed on the aforementioned components, and thus, compared with in a case where grooves are formed in other layers disposed under the overcoat layer 900, is more desirable in terms of difficulty of processes, and the reliability of the display apparatus may be secured.

The first groove GV1 may include a through hole in which an area of the overcoat layer 900 is removed in a thickness direction (e.g., the z direction). The first groove GV1 may expose a top surface of a layer disposed under the overcoat layer 900. The first groove GV1 may expose the top surface of the color filter layer CFL. The first groove GVI may be formed through a photo process. In a case where a photo pattern is added when the overcoat layer 900 is formed, the first groove GV1 may be formed without adding masks to form the grooves.

Referring to FIGS. 6A and 6B, in a plan view, an area of the overcoat layer 900 may include a mesh pattern in which the first grooves GV1 having a through hole shape are provided. Although FIG. 6B illustrates that the first grooves GV1 have a square shape at regular intervals, the disclosure is not limited thereto. In an embodiment, the first grooves GV1 may be arranged at irregular and arbitrary intervals, and may have a square, a polygon, a circle, an ellipse, or an amorphous shape.

A center width W1 of the first groove GV1 may be from about 1 μm to about 100 μm. The center width W1 of the first groove GV1 may indicate a width in a plan view, and may also indicate a width beyond a center point of the first groove GV1. As the center width W1 of the first groove GV1 is about 1 μm or greater, stress due to the overcoat layer 900 may be reduced, and as the center width W1 of the first groove GV1 is not greater than about 100 μm, the layers disposed under the overcoat layer 900 may be sufficiently covered.

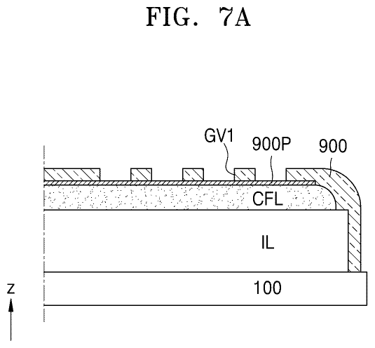

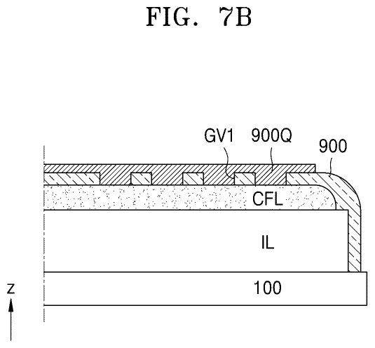

FIGS. 7A and 7B are cross-sectional views schematically illustrating a portion of the non-display area NDA of the display apparatus 1 according to an embodiment. In FIGS. 7A and 7B, same reference numerals as FIGS. 6A and 6B indicate same members, and therefore, descriptions thereof will not be repeatedly given.

In an embodiment, the display apparatus 1 may include a sub capping layer 900P disposed under or on the overcoat layer 900. The sub capping layer 900P may overlap the first groove GV1. The sub capping layer 900P may include one or more inorganic materials from among aluminum oxide, titanium oxide, tantalum oxide, hafnium oxide, zinc oxide, silicon oxide, silicon nitride, and silicon oxynitride.

Referring to FIG. 7A, in an embodiment, the sub capping layer 900P may be disposed between the color filter layer CFL and the overcoat layer 900. The first groove GV1 of the overcoat layer 900 may expose the top surface of the sub capping layer 900P. A thickness of the sub capping layer 900P may be less than a thickness of the overcoat layer 900. The sub capping layer 900P may overlap the first groove GV1 and thus may prevent exposure of the top surface of the color filter layer CFL through the first groove GV1.

Referring to FIG. 7B, in an embodiment, the sub capping layer 900Q may be disposed on the overcoat layer 900. At least a portion of the sub capping layer 900Q may be buried into (or disposed in) the first groove GV1. The sub capping layer 900Q may prevent exposure of the top surface of the color filter layer CFL through the groove layer GV1, and may also planarize unevenness of the top surface of the overcoat layer 900 formed by the first grooves GV1, to thereby improve the reliability of the display apparatus 1. For example, the sub capping layer 900Q may prevent a layer stacked on the overcoat layer 900 from lifting or becoming delaminated due to unevenness caused due to the first grooves GV1.

The sub capping layer 900Q may be formed together with the capping layer disposed on the overcoat layer 900 in the display area DA, which is described with reference to FIG. 5. For example, the sub capping layer 900Q may be formed without additional processes.

Although FIG. 7B illustrates that the sub capping layer 900Q formed in a thickness greater than the thickness of the overcoat layer 900 to completely fill the first groove GV1 and cover the top surface of the overcoat layer 900, the embodiments are not limited thereto. For example, the sub capping layer 900Q may be formed in a thickness not greater than the thickness of the overcoat layer 900, and thus may be arranged only in the first groove GV1 or may fill the first groove GV1 only up to a certain height.

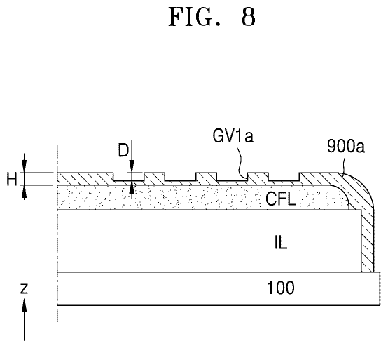

FIG. 8 is a schematic cross-sectional view schematically illustrating a portion of the non-display area NDA of the display apparatus 1 according to an embodiment. In FIG. 8, same reference numerals as in FIG. 6A indicate same members, and therefore, descriptions thereof will not be repeatedly given.

Referring to FIG. 8, the first groove GV1a provided in the overcoat layer 900a may include a groove obtained by removing a portion of the overcoat layer 900a in a direction toward the substrate 100. For example, a depth D of the first groove GV1a may be less than the thickness H of the overcoat layer 900a. The depth D of the first groove GV1a may be at least about 0.4 times the thickness H of the overcoat layer 900a. The first groove GV1a may be formed through a halftone mask process.

Unlike in the embodiment shown in FIG. 6A, as the first groove GV1a is provided as a groove that is not a through hole (an opening), the first groove GV1a may not expose a top surface of a layer disposed under the overcoat layer 900a. For example, the bottom surface of the overcoat layer 900a covers an entire area of the top surface of the color filter layer CFL and therefore has improved reliability, and a bonding force between the overcoat layer 900a and the color filter layer CFL may be enhanced.

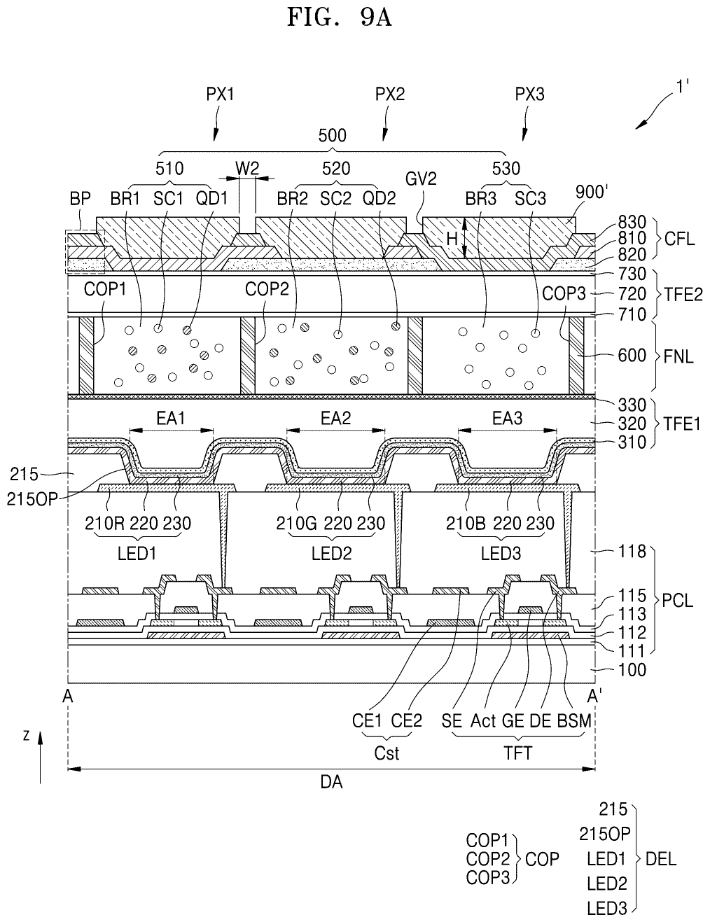

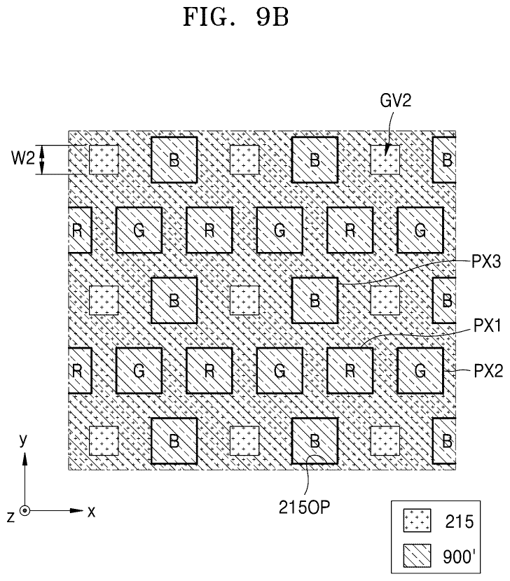

FIGS. 9A and 9B are a cross-sectional view and a plan view respectively schematically illustrating a portion of the display area DA of the display apparatus 1′ according to an embodiment. In FIGS. 9A and 9B, same reference numerals as in FIG. 5 indicate same members, and therefore, descriptions thereof will not be repeatedly given.

In an embodiment, multiple second grooves GV2 arranged in the display area DA may be provided in the overcoat layer 900′. The second groove GV2 may include a through hole or a groove obtained by removing a portion of the overcoat layer 900′ in the thickness direction (e.g., the z direction). The second groove GV2 may be formed through a photo process and/or a halftone mask process.

In a plan view, an area of the overcoat layer 900′ may include a mesh pattern in which the second grooves GV2 are provided. Although FIG. 9B illustrates that the second grooves GV2 have a square shape at regular intervals, the disclosure is not limited thereto. In an embodiment, the second grooves GV2 may be arranged at irregular and arbitrary intervals, and may have a square, a polygon, a circle, an ellipse, or an amorphous shape.

The second grooves GV2 may be arranged in non-emission areas among the first subpixel PX1, the second subpixel PX2, and the third subpixel PX3. In a plan view, the second groove GV2 may overlap at least any one of the first bank layer 215, the second bank layer 600, and the light-blocking portion BP. In an embodiment, by arranging the second groove GV2 in the non-emission area, an impact on paths of light, (e.g., the light emitted from the display element is refracted at a side surface of the overcoat layer 900′ defining the second groove GV2) may be prevented.

A center width W2 of the second groove GV2 may be less than an interval between the subpixels. The center width W2 of the second groove GV2 may be in a range of about 1 μm to about 100 μm. The center width W2 of the second groove GV2 may indicate a width in a plan view, and may also indicate a width beyond a center point of the second groove GV2.

In an embodiment, the overcoat layer 900′ disposed all over the display apparatus 1′ includes the second groove GV2 located in the display area DA, and therefore, a tensile strength of an entire area of the display panel, as well as the outer edge portion of the display apparatus, may be reduced, and bending of the display panel may be prevented.

Structures of the display element layer DEL, the color filter layer CFL, and the overcoat layer 900′ described above with reference to FIGS. 5 to 9B may be applied to the case in which the display element layer DEL includes the color conversion-transmissive layer FNL, as shown in FIGS. 2 and 5, the disclosure is not limited thereto. As an embodiment, the light-emitting diode layer of the display apparatus may include light-emitting diodes configured to emit light of red, green, or blue color, and the color conversion-transmissive layer FNL may be omitted. For example, in case that the light-emitting diodes are respectively configured to emit light of different colors, the color conversion-transmissive layer FNL may be omitted. According to an embodiment, the display apparatus may include the overcoat layer 900′ having the structure described above with reference to FIGS. 6A to 9B to reduce defects occurring due to tearing of the films.

According to embodiments, a robust display apparatus may be provided. However, the scope of the disclosure is not limited thereto.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus comprising:
a substrate comprising a display area and a non-display area surrounding the display area;
a display element layer disposed on the substrate and comprising at least one display element;
an encapsulation layer disposed on the display element layer and comprising at least one inorganic encapsulation layer and at least one organic encapsulation layer;
a color conversion-transmissive layer disposed on the encapsulation layer and configured to convert light emitted from the at least one display element into another color;
a color filter layer disposed on the color conversion-transmissive layer; and
an overcoat layer disposed on the color filter layer and extending from the display area to the non-display area, wherein the overcoat layer includes a plurality of first grooves in the non-display area.

2. The display apparatus of claim 1, wherein a bottom surface of the overcoat layer comprises a concave surface corresponding to a convex surface included in a top surface of the color filter layer.

3. The display apparatus of claim 1, wherein the overcoat layer is in direct contact with the color filter layer and covers an edge of the color filter layer.

4. The display apparatus of claim 1, wherein the plurality of first grooves expose at least a portion of a top surface of the color filter layer.

5. The display apparatus of claim 1, wherein a center width of each of the plurality of first grooves is in a range of about 1 μm to about 100 μm.

6. The display apparatus of claim 1, wherein the overcoat layer comprises an organic material layer.

7. The display apparatus of claim 1, wherein a thickness of the overcoat layer is greater than a thickness of the color filter layer.

8. The display apparatus of claim 1, wherein a thickness of the overcoat layer is in a range of about 3 μm to about 8 μm.

9. The display apparatus of claim 1, further comprising:
a sub capping layer directly contacting the overcoat layer and overlapping the plurality of first grooves.

10. The display apparatus of claim 1, further comprising:
a first bank layer disposed on the substrate, the first bank layer including an opening defining an emission area of the at least one display element, and
wherein the overcoat layer further comprises a plurality of second grooves disposed in the display area and overlapping the first bank layer in a plan view.

11. The display apparatus of claim 10, wherein the color conversion-transmissive layer comprises:
a color converter comprising a plurality of quantum dots; and
a second bank layer surrounding the color converter, and
wherein the plurality of second grooves overlap the second bank layer in a plan view.

12. The display apparatus of claim 1, wherein
the color filter layer comprises a first color filter configured to transmit light of a first color, a second color filter configured to transmit light of a second color, a third color filter configured to transmit light of a third color, and a light-blocking portion partitioning the second color filter and the third color filter, and
the light-blocking portion comprises at least two overlapping color layers selected from a first color layer, a second color layer, and a third color filter respectively, the light-blocking portion comprising materials identical to materials of the first color filter, the second color filter, and the third color filter.

13. The display apparatus of claim 1, wherein the encapsulation layer comprises:
a first inorganic encapsulation layer, a first organic encapsulation layer, and a second inorganic encapsulation layer, which are sequentially stacked on each other, and
the color conversion-transmissive layer is in direct contact with the second inorganic encapsulation layer.

14. A display apparatus comprising:
a substrate comprising a display area and a non-display area surrounding the display area;
a display element layer disposed on the substrate and comprising at least one display element;
an encapsulation layer disposed on the display element layer and comprising at least one inorganic encapsulation layer and at least one organic encapsulation layer;
a color filter layer disposed on the encapsulation layer and comprising a first color filter configured to transmit light of a first color, a second color filter configured to transmit light of a second color, a third color filter configured to transmit light of a third color, and a light-blocking portion partitioning the first color filter, the second color filter, and the third color filter; and
an overcoat layer comprised of an organic material disposed on the color filter layer to cover an edge of the color filter, the overcoat layer comprising a plurality of grooves.

15. The display apparatus of claim 14, wherein
a center width of each of the plurality of grooves is in a range of about 1 μm to about 100 μm, and
the plurality of grooves expose at least a portion of a top surface of the color filter layer.

16. The display apparatus of claim 14, wherein the plurality of grooves comprise a plurality of first grooves in the non-display area and a plurality of second grooves at least partially overlapping the light-blocking portion in the display area.

17. The display apparatus of claim 14, wherein
the light-blocking portion comprises a first color layer, a second color layer, and a third color layer that overlap one another, and
the first color layer, the second color layer, and the third color layer respectively comprise materials identical to materials of the first color filter, the second color filter, and the third color filter.

18. The display apparatus of claim 17, wherein a bottom surface of the overcoat layer comprises a concave surface corresponding to a convex surface included in a top surface of the color filter layer.

19. The display apparatus of claim 14, wherein a thickness of the overcoat layer is in a range of about 3 μm to about 8 μm.

20. The display apparatus of claim 14, further comprising:
a sub capping layer extending from the display area to the non-display area, the sub capping layer being disposed in the plurality of grooves.
